(19) United States
(12) Patent Application Publication
(10) Pub. No.: US 2002/0160319 A1
(43) Pub. Date: Oct. 31, 2002

(54) Method for forming resist film

(75) Inventor: Hiroki Endo, Kanagawa (JP)

Correspondence Address: Carrier, Blackman & Associates, P.C., 24101 Novi Road #100, Novi, MI, 48375, US

(73) Assignee: Tokyo Ohka Kogyo Co. Ltd., Kanagawa (JP)

(21) Appl. No.: 10/132,760

(22) Filed: Apr. 25, 2002

(30) Foreign Application Priority Data
Apr. 25, 2001 (JP) 2001-127629

(51) Int. Cl. G03F 7/16

(52) U.S. Cl. 430/327; 430/330; 430/935

(57) ABSTRACT

A film forming method for obtaining a resist film of a uniform thickness on a substrate includes the steps of treating the surface of the substrate is treated with a HMDS (hexamethyldisilazane) process, then a pre-wetting process is conducted, and a resist liquid is applied just after the pre-wetting process is competed. In the pre-wetting process, a solvent is used which is capable of dissolving the resist liquid, and preferably the same solvent as used in the resist liquid. The application of both the resist liquid and the pre-wet liquid are conducted by rotating the substrate by means of a spinner after the liquid is dripped at the center of the substrate. It is preferable that the application of the resist liquid is contiguous to the application of the pre-wet liquid as much as possible. After the application of the resist liquid is completed, the substrate is put on a hot plate, a baking process is conducted, and a resist film is formed.

### BACKGROUND OF THE INVENTION

1. Field of the Invention

The present invention relates to a method for forming a resist film on a surface of a substrate such as a semiconductor wafer or the like.

2. Description of Relevant Art

In general, a photo-resist shows a hydrophobic property, and for increasing adherence of this photo-resist to a surface of a substrate, it is enough to make the surface of a substrate have a hydrophobic property. It is disclosed that HMDS (hexamethyldisilazane) treatment is applied onto the surface of a substrate for this purpose, for example in Japanese Patent Application Publication No. Hei 11-243090 (1999).

For suppressing phenomena such as undercut of a negative resist or trailing skirts of a positive resist which are caused when the HMDS (hexamethyldisilazane) treatment is conducted to the substrate, in Japanese Patent Application Publication No. 2000-150339 (2000) was made a proposal of applying the HMDS onto an undercoat film which is formed on the substrate in advance.

Also, conventionally, a spin coating method has been employed for applying a photo-resist upon a surface of a substrate. However, according to this method, there is a tendency that the thickness of a resist film formed on a peripheral portion of the substrate comes to be greater than that formed on other parts. For resolving such a problem, in Japanese Patent Application Publication No. Hei 5-136042 (1993), it is disclosed that only an outer peripheral portion of a chucking table (spinner) for sucking and rotating a substrate is brought into a lower temperature condition so as to make the vaporization rate of a solvent within a resist liquid slow, which is applied on a peripheral portion of the substrate, and thereby a uniform thickness of the resist film can be obtained.

In the case where a resist film is formed by means of the spin coating method upon a surface of a substrate on which the HMDS (hexamethyldisilazane) treatment was conducted, there is a drawback that the film thickness of the resist film on a peripheral portion of the substrate comes to be greater in the same manner as in the conventional art. For resolving this, the means as is disclosed in the Japanese Patent Application Publication No. Hei 5-136042 (1993) may be employed. However, since it requires the mechanism for controlling the temperature of only one part of the spinner to be low, the apparatus comes to be complicated. Also, even if the temperature of only one part of the spinner is made low, there is not so much improvement in the uniformization of the thickness of the formed resist film.

### SUMMARY OF THE INVENTION

Therefore, according to the present invention, for resolving the drawback mentioned above, first, there is provided a method for forming a resist film, comprising the following steps of: treating a surface of a substrate with a HMDS (hexamethyldisilazane) process; applying and spreading a resist liquid, which is kept at a temperature lower than that of a circumferential portion of the substrate, onto the surface after said HMDS process is completed; and thereafter baking the resist liquid.

Keeping the resist liquid at a temperature lower than the substrate's circumferential temperature delays evaporation of a solvent contained within the resist liquid, thereby a uniform film thickness can be obtained.

Also, according to the present invention, secondly, there is provided a method for forming a resist film, comprising the following steps of: treating a surface of a substrate with a HMDS (hexamethyldisilazane) process; treating the surface of the substrate with a pre-wetting process by using a solvent, which is capable of dissolving a resist liquid; applying and spreading the resist liquid onto the surface after said pre-wetting process is completed; and thereafter baking the resist liquid. Preferably, the pre-wetting solvent is the same solvent as is used in the resist liquid.

Since the pre-wetting process uses the solvent, into which the resist liquid is dissolved, even if the solvent within the resist liquid evaporates, the amount of evaporation can be resupplied, thereby a uniform film thickness can be obtained.

Further, the above-mentioned two methods can be applied at the same time.

Also, in the case of conducting the pre-wetting process, it is preferable that the application of the resist liquid is started just after the pre-wetting process or within ten (10) seconds after the discharge of the pre-wetting solvent. Also, it is preferable that the solvent used in the pre-wetting process has a vapor ratio (at 20° C.) in the range from 0.1 to 10 on the assumption that the vapor ratio of n-butyl acetate is 1.

Furthermore, for forming a resist film, it is also possible to provide a plurality of application nozzles which are selectively used depending upon a viscosity of the resist liquid.

With this, the adjustment of the film thickness of the resist film can be achieved by only replacing the nozzles without changing other factors such as the temperature, the rotation speed, or the like.

### BRIEF DESCRIPTION OF THE DRAWINGS

FIG. 1 is a block diagram for explaining sequential steps of a method for forming a resist film according to the present invention; and

FIGS. 2(a) to 2(c) are views for showing a condition where HMDS is applied, a condition where a resist liquid is applied just after a pre-wetting process, and a condition where a resist film is baked, respectively.

### DETAILED DESCRIPTION OF THE INVENTION

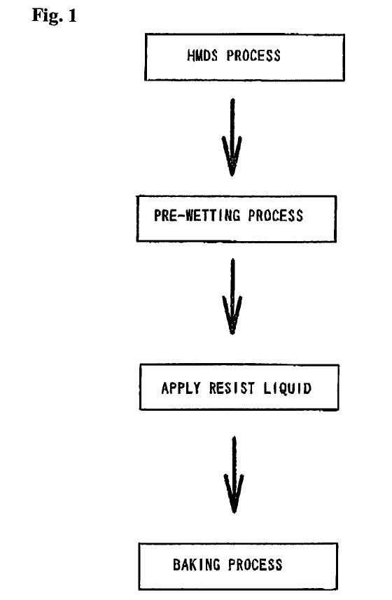

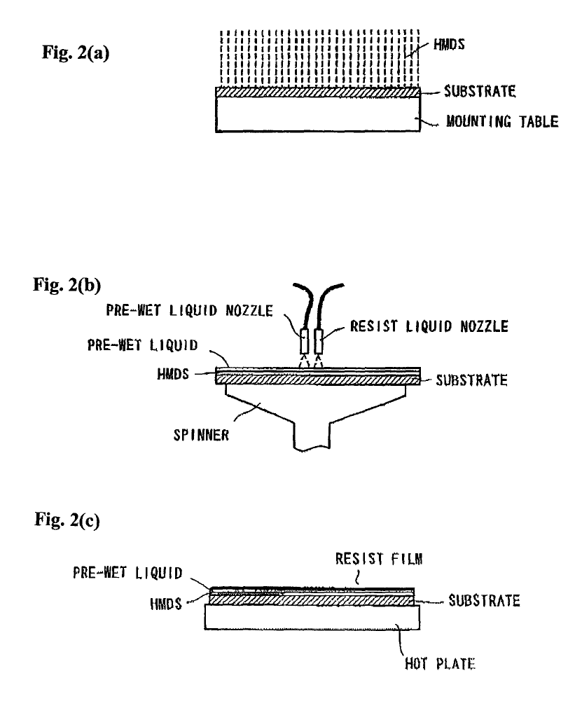

Hereinafter, embodiments according to the present invention will be fully explained with reference to the attached figures. FIG. 1 is a block diagram for explaining sequential steps of a method for forming a resist film according to the present invention; and FIGS. 2(a) to 2(c) are views for showing a condition where HMDS is applied, a condition where a resist liquid is applied just after a pre-wetting process, and a condition where a resist film is baked, respectively.

First, a surface of a substrate is treated by a HMDS process. Specifically, as shown in FIG. 2(a), the substrate is put on a mounting table, and it is exposed in an atmosphere of HMDS vapor. Other than this method, it is also possible to secure the substrate on a vacuum-type spinner chuck via suction, and apply a HMDS liquid while the substrate is rotated.

Also, before treating the surface with the HMDS process, an undercoat process may be conducted on the surface of the substrate by using a processing liquid containing nitrogen atoms therein.

Next, the surface is treated with a pre-wetting process. As a pre-wet liquid, a solvent is used, which can dissolve a resist liquid therein. Specifically, a solvent having a vapor ratio (at 20° C.) in the range from 0.1 to 10 on the assumption that the vapor ratio (at 20° C.) of n-butyl acetate is 1 is used, and more specifically, a low volatile solvent such as ethyl lactate, ethylene glycol monoethyl ether acetate, or the like is used. However, this pre-wetting process may be omitted if the resist liquid is used under the condition at a temperature lower than that of the ambient atmosphere.

Also, for applying the pre-wet liquid, as shown in FIG. 2(b), the substrate is sucked and fixed on a spinner chuck, and it is rotated by a spinner after the pre-wet liquid is dripped at the center of the substrate. Or, the pre-wet liquid may be dripped while the substrate is rotated.

A resist liquid is applied just after the pre-wetting process is completed. For applying the resist liquid, in the same manner as the pre-wet liquid, the substrate is rotated by means of the spinner after the resist liquid is dripped at the center of the substrate. Since it is preferable that the application of the resist liquid is contiguous to the application of the pre-wet liquid as much as possible (within ten (10) seconds after the discharge of the pre-wet liquid), as shown in FIG. 2(b), both a pre-wet liquid nozzle and a resist liquid nozzle may be located above the substrate so as to apply the resist liquid after the application of the pre-wet liquid in a continuous manner.

Also, a plurality of resist liquid nozzles may be prepared depending upon a viscosity of the resist liquid, so that the nozzles can selectively be used depending upon the film thickness of the resist film to be desired.

When the application of the resist liquid is completed in the manner as mentioned above, as shown in FIG. 2(c), the substrate is put on a hot plate, and it is treated with a baking process so as to evaporate the solvent contained within the resist liquid, and a resist film is formed.

As is fully explained in the above, according to the present invention, at the time of applying and spreading a resist liquid onto the surface of the substrate after being treated with the HMDS process, the resist liquid is kept at a temperature lower than the substrate's circumferential temperature, and thereby the resist film formed on the substrate surface has a uniform thickness.

Also, according to the present invention, the substrate is treated with a pre-wetting process after being treated with the HMDS process, and thereafter a resist liquid is applied, and thereby the resist film formed on the substrate surface has a uniform thickness.

Further, for applying the resist liquid, the plurality of application nozzles are prepared so as to be used selectively depending upon a viscosity of the resist liquid, and thereby the film thickness of the resist film can be adjusted easily.

Although there have been described in detail what are the present embodiments of the invention, it will be understood by persons skilled in the art that variations and modifications may be made thereto without departing from the gist, spirit or essence of the invention. The scope of the invention is indicated by the appended claims.

What is claimed is:

1. (amended) A method for forming a resist film, comprising the following steps of:
treating a surface of a substrate with a HMDS (hexamethyldisilazane) process;
applying and spreading a resist liquid onto the surface after said HMDS process is completed, said resist liquid being kept at a temperature lower than that of a circumferential portion of said substrate; and
thereafter baking said resist liquid.

2. (amended) A method for forming a resist film, comprising the following steps of:
treating a surface of a substrate with a HMDS (hexamethyldisilazane) process;
treating the substrate with a pre-wetting process using a solvent, into which a resist liquid is dissolved;
applying and spreading a resist liquid onto the surface after said pre-wetting process is completed; and
thereafter baking the resist liquid.

3. (amended) A method for forming a resist film, comprising the following steps of:
treating a surface of a substrate with a HMDS (hexamethyldisilazane) process;
treating the substrate with a pre-wetting process using a solvent, into which a resist liquid is dissolved;
applying and spreading a resist liquid onto the surface after said pre-wetting process is completed, said resist liquid being kept at a temperature lower than a circumferential temperature; and
thereafter baking the resist liquid.

4. (amended) A method for forming a resist film, as described in claim 2, wherein the application of said resist liquid is started within ten (10) seconds after the discharge of the pre-wetting solvent.

5. (amended) A method for forming a resist film, as described in claim 2, wherein the solvent used in said pre-wetting process has a vapor ratio at 20° C. in the range from 0.1 to 10 on the assumption that the vapor ratio of n-butyl acetate is 1.

6. (amended) A method for forming a resist film, as described in claim 1, wherein a plurality of application nozzles are provided for applying said resist liquid onto the substrate surface, said plurality of application nozzles being selectively used depending upon a viscosity of said resist liquid.

7. (new) A method for forming a resist film, as described in claim 2, wherein the application of said resist liquid is started just after said pre-wetting process.

8. (new) A method for forming a resist film, as described in claim 3, wherein the application of said resist liquid is started within ten (10) seconds after the discharge of the pre-wetting solvent.

9. (new) A method for forming a resist film, as described in claim 3, wherein the application of said resist liquid is started just after said pre-wetting process.

10. (new) A method for forming a resist film, as described in claim 3, wherein the solvent used in said pre-wetting process has a vapor ratio at 20° C. in the range from 0.1 to 10 on the assumption that the vapor ratio of n-butyl acetate is 1.

11. (new) A method for forming a resist film, as described in claim 2, wherein a plurality of application nozzles are provided for applying said resist liquid onto the substrate surface, said plurality of application nozzles being selectively used depending upon a viscosity of said resist liquid.

12. (new) A method for forming a resist film, as described in claim 3, wherein a plurality of application nozzles are provided for applying said resist liquid onto the substrate surface, said plurality of application nozzles being selectively used depending upon a viscosity of said resist liquid.

13. (new) A method for forming a resist film, as described in claim 4, wherein a plurality of application nozzles are provided for applying said resist liquid onto the substrate surface, said plurality of application nozzles being selectively used depending upon a viscosity of said resist liquid.

14. (new) A method for forming a resist film, as described in claim 5, wherein a plurality of application nozzles are provided for applying said resist liquid onto the substrate surface, said plurality of application nozzles being selectively used depending upon a viscosity of said resist liquid.

15. (new) A method for forming a resist film, as described in claim 7, wherein a plurality of application nozzles are provided for applying said resist liquid onto the substrate surface, said plurality of application nozzles being selectively used depending upon a viscosity of said resist liquid.
